(19) United States
(12) Patent Application Publication
(10) Pub. No.: US 2007/0222088 A1
(43) Pub. Date: Sep. 27, 2007

(54) Overlay Metrology Mark

(75) Inventors: Nigel P. Smith, Hsinchu (TW); Michael J. Hammond, York (GB)

Correspondence Address: PERKINS COIE LLP;PATENT-SEA, P.O. BOX 1247, SEATTLE, WA, 98111-1247, US

(73) Assignee: AOTI Operating Company, Inc,, Bend, OR (US)

(21) Appl. No.: 10/549,860

(22) PCT Filed: Apr. 8, 2004
(86) PCT No.: PCT/GB04/01536

§ 371 Date: Jul. 13, 2006

(30) Foreign Application Priority Data
Apr. 8, 2003 (GB) 0308086.8
Apr. 9, 2003 (GB) 0308180.9

(51) Int. Cl. H01L 23/544; H01L 21/66

(52) U.S. Cl. 257/797; 438/14

(57) ABSTRACT

An overlay metrology mark for determining the relative position between two or more layers of an integrated circuit structure comprising a first mark portion associated with and in particular developed on a first layer and a second mark portion associated with and in particular developed on a second layer, wherein the first and second mark portions together constitute, when the mark is properly aligned, at least one pair of test zones, each test zone comprising a first mark section formed as part of the first mark portion and a second mark section formed as part of the second mark portion each comprising a plurality of elongate rectangular mark structures in parallel array adjacently disposed to form the said test zone such that the mark structures in each test zone are in alignment in a first direction within the test zone but are substantially at 90° with respect to the mark structures of at least one other test zone in alignment in a second direction, and wherein the test zones making up the or each pair are laterally displaced relative to each other along one of the said directions. A method of marking and a method of determining overlay error are also described.

The invention relates to overlay metrology during semiconductor device fabrication, and in particular to an overlay alignment mark to facilitate alignment and/or measure the alignment error of two layers on an integrated circuit structure during its fabrication.

Modern semiconductor devices, such as integrated circuits, are typically fabricated from wafers of semiconductor material. In particular, a wafer is fabricated comprising a succession of patterned layers of semiconductor material.

Circuit patterns are fabricated using a variety of long established techniques, for example making use of lithographic techniques. Precise positioning and alignment during fabrication is of great significance in the manufacture of accurate patterns. For example, alignment control of the exposure tool is important in ensuring a consistent process. Alignment methodologies are established in this regard, in which statistical and modelling techniques are used to determine the alignment of a reticle with a pattern created by or in association with the exposure tool to facilitate alignment of the exposure tool. The technique typically exploits images generated within the exposure tool optics, or projected onto the wafer by the exposure tool optics. Similar model-based and statistical methods have been employed to align for example an exposure tool during pattern fabrication.

Although such alignment technology has an established utility, and is important in device fabrication, it relates to alignment of fabrication tooling only. This can be a limitation in relation to integrated circuit structures comprised of a succession of pattern layers of semiconductor material where it is desirable in relation to such wafers to provide a methodology enabling a determination of the misregistration between fabricated layers themselves.

Overlay metrology in semiconductor device fabrication is used to determine how well one printed layer is overlaid on a previously printed layer. Close alignment of each layer at all points within the device is crucial for reaching the design goals and hence the required quality and performance of the manufactured device. It is consequently of importance for the efficiency of the manufacturing process that any alignment error between two patterned layers on a wafer, especially successive patterned layers can be measured quickly and accurately. It is similarly important to be able to measure any alignment error between successive exposures in the same layer, and where reference is made herein for convenience to two layers it will be understood where appropriate to apply equally to two exposures in the same layer.

Misregistration between layers is referred to as overlay error. Overlay metrology tools are used to measure the overlay error. This information may be fed into a closed loop system to correct the overlay error.

Current overlay metrology employs optically readable target patterns, printed onto the successive layers of a semiconductor wafer during fabrication. The relative displacement of two successive layers is measured by imaging the patterns at high magnification, digitizing the images, and processing the image data using various known image analysis algorithms to quantify the overlay error. Overlay metrology techniques thus involve the direct measurement of misregistration between patterns provided in direct association with each of the fabricated layers under investigation. In particular, patterns are developed in or on the surface of each of the layers, or may be latent images, rather than images generated within or projected from the optics of an imaging instrument.

The pattern of the target mark may be applied to the wafer by any suitable method. In particular, it is often preferred that the mark is printed onto the wafer layers for example using photolithographic methods. Typically, the same technique is used to apply overlay target marks on each of two wafer layers to be tested to enable alignment information to be measured which is representative of the alignment of the layers. Accuracy of layer alignment should correspond to accuracy of circuit pattern alignment within the fabricated wafer.

Current overlay metrology is normally practised by printing targets with rectangular symmetry. For each measurement two targets are printed, one in the current layer and one in a previous layer, or one in association with each pattern in a common layer. The choice of which previous layer to use is determined by process tolerances. The two targets have a nominally common centre, but are printed with different sizes so that they can be differentiated. Normally, but not always, the target printed in the current layer is the smaller of the two targets. An overlay measurement in such a system is the actual measured displacement of the centres of the two targets.

Current preferred practice is that the size of the targets is designed such that both can be imaged simultaneously by a bright-field microscope. Imaging considerations determine that the larger of the two targets is typically a 25 μm square on the outside. This arrangement permits capture of all of the necessary data for the performance of the measurement from a single image. Measurements at a rate of one in every two seconds or less are possible using current technology.

The procedure necessarily requires that the target and its image are symmetric, since otherwise there is no uniquely defined centre point. Without symmetry there is an uncertainty in the measurement, which may be more than can be tolerated. Within that general requirement, optimal sizes and shapes of current designs of targets to be measured are well known. The targets are positioned in the scribe area at the edge of the fabricated circuit.

It is generally desirable that the measurement targets maintain axial symmetry about the optical axis of the measurement tool, since accurate measurement requires very close control of image aberrations. To achieve this it can also therefore be advantageous to use marks at or with symmetry centred about the system axis.

Marks exhibiting symmetry are usually aligned in a known and consistent relationship relative to the crystal lattice of the wafer. Where this defines “X” and “Y” directions these are conveniently used as reference directions for the imaging apparatus. The “X” and “Y” planes are more specifically relevant to the wafer than they are to the optics, but it is normal to choose to align the wafer such that “X” corresponds to the horizontal and “Y” to the vertical as viewed through the microscope. It is possible in principle to measure at any other orientation, but for many mark symmetries advantages are conferred if the marks are arranged to have symmetry about what are conventionally termed the “X” and the “Y” axes, which allows the optimum performance to be obtained from the metrology apparatus.

In most prior art systems, measurements are therefore made from the targets by computing a centre line for each different target. The overlay measurement is the difference in the centre lines. Most of the target designs in general use permit measurement of the vertical and horizontal overlay displacement from a single image.

Measurement errors must be controlled to a very small amount. Errors known to arise are classified as random errors, characterized by determination of measurement precision; and systematic errors, characterized by tool induced errors, tool-to-tool measurement differences and errors introduced by asymmetry in the targets being measured. Successful application of overlay metrology to semiconductor process control is generally held to require that, combined, these errors are less than 10% of the process control budget. This measurement error budget is in practice in the range 1 to 5 nm, and will remain so in the foreseeable future.

Measurement precision is easily determined by analysis of the variations of repeated measurements. Different forms of precision may be determined by well known appropriate methods, allowing determination of the static, short-term and long-term components of precision.

Determining the contribution of the measurement tool alone to errors is achieved by comparing measurements made with the target in its normal presentation with a measurement made after rotating the target by 180° with respect to the imaging system. Ideally the measurement will simply change sign. The average of the measurements at 0° and 180° is called Tool Induced Shift (TIS), as is well known to those skilled in the art, and is widely accepted as a measure of the tool's systematic error contribution. Measurements of TIS differ from tool to tool and with process layer. Subtraction of the estimated TIS error from the measurements allows removal of the TIS error from the measurements, but at the expense of the additional time taken to measure the target twice.

Different tools, even when of the same type, will make slightly different measurements, even after allowing for precision and TIS errors. The magnitude of this error can be determined experimentally by comparing the averages of repeated measurements at 0° and 180° on two or more tools.

The contributions of precision, TIS and tool-to-tool differences are normally combined through a root-sum-square product, or alternative appropriate method, to determine the total measurement uncertainty due to the measurement process. The total measurement uncertainty must be less than 10% of the overall overlay budget for the process if the metrology is to have value. Existing measurement tools and procedures achieve a total uncertainty within that required for current process technologies but insufficient for future requirements.

By contrast, although the contribution of asymmetry in the measurement target itself is widely understood it is not normally determined. It is known that in many cases it can be much larger than the tool contribution to measurement uncertainty. There are two sources of error to be considered:
1. Imperfection in the manufacture of the target which leads to an uncertainty in its location. An example of this is physical asymmetry of the target, caused perhaps by uneven deposition of a metal film.
2. Difference in the displacement of the two layers at the measurement target and the genuine overlay of the same layers in the device being manufactured. These can arise from errors in the design and manufacture of the reticles used to create the patterns on the wafer, proximity effects in the printing process and distortion of the films after printing by other process steps.

These measurement errors represent a practical limitation of the current state of the art which causes severe problems in the application of overlay metrology to semiconductor process control.

Improvements to the first of these problems can sometimes be achieved by fabricating the features in the measured targets from much smaller objects—lines or holes. The common term for this technique is “segmentation”. These smaller features are printed at the design rule for the process, currently in the range 0.1-0.2 μm, and are grouped close together. They are too small to be individually resolved by the optical microscopes used in overlay metrology tools. The small features are grouped into larger shapes in the pattern of traditional overlay targets. The use of small features avoids some of the mechanisms causing imperfections in the shape of the manufactured targets, in part by taking advantage of the optimization of the manufacturing process for objects of this size and shape.

A further problem is introduced by the size of the targets, which are a significant fraction of the space available in the scribe area surrounding the devices being fabricated. It is desired that the size of these areas be reduced, which means that it is also highly desirable that the measurement targets be made smaller. However, the size of the target cannot be reduced too much, since accurate measurement requires that the measured features are not smaller than the resolution of the microscope system, and achieving good precision requires that as many as possible of such features are visible in the image.

It has been shown (Smith, Nigel P.; Goelzer, Gary R.; Hanna, Michael; Troccolo, Patrick M., “Minimizing overlay measurement errors”, August 1993, Proceedings of SPIE Volume: 1926 Integrated Circuit Metrology, Inspection, and Process Control VII, Editor(s): Postek, Michael T) that space must be left between the features printed from the two layers else the proximity of one to another causes an error in the measurement. The magnitude of this error depends on the resolution of the imaging microscope system, but must be 5 μm or greater in practical designs if the measurement error is to be contained within practical limits. This proximity effect further limits the extent to which the size of the targets can be reduced.

However, high speed is one of the key advantages of existing overlay metrology practice, and any process development must not lose this advantage if it is to be viable in production use. This requirement means that uncertainty reduction by the use of repeated measurements is highly undesirable. There is thus a general desire to develop alternative overlay patterns and/or analysis methods which apply the basic principles of existing metrologies but in a manner that mitigates some or all of these errors to produce an improved fabrication metrology, and in particular a metrology offering improved accuracy without substantial loss of throughput speed. Moreover, it is desirable to use existing imaging tooling, and so desirable to retain the generally square or rectangular mark geometry familiar in the art.

In accordance with the present invention in a first aspect an overlay metrology mark for determining the relative position between two or more layers of an integrated circuit structure comprises a first mark portion associated with a first layer and a second mark portion associated with a second layer, wherein the first and second mark portions together constitute, when the mark is properly aligned, at least one pair of test zones, each test zone comprising a first mark section formed as part of the first mark portion and a second mark section formed as part of the second mark portion each comprising a plurality of elongate rectangular mark structures in parallel array adjacently disposed to form the said test zone such that the mark structures in each test zone are in alignment in a first direction within the test zone but are substantially at 90° with respect to the mark structures of at least one other test zone in alignment in a second direction, and wherein the test zones making up the or each pair are laterally displaced relative to each other along one of the said directions.

It should be emphasised that a mark in accordance with the invention is an overlay metrology mark, in which a mark portion is directly associated with each of the first and second layer to provide a directly measurably indication of the misregistration or overlay error between the layers under investigation. In particular, each mark portion is preferably developed in or on the surface of the wafer layer in such direct association. For example, each mark portion may be printed onto the wafer layer, for example using the same technique which is used to apply the circuit pattern, and for example using photolithographic methods. Alternatively, a mark may be a latent image. The two mark portions, comprising the complete overlay metrology mark, are imaged together to obtain a quantification of any overlay error.

The invention discloses novel target designs that address the disadvantages of the existing technology, in particular offering generally improved measurement performance in relation to the control of errors discussed above without sacrificing advantages in relation to speed of processing and otherwise.

In order to give effective X-Y information, many prior art mark designs which are similarly made up of rectangular test structures divide the mark area into four zones, respectively corresponding to the X and Y directions for each of the reference and overlay markings. Given the symmetry of the optics commonly used, there can be advantages if these are disposed around the optic axis of the instrument, in a square array.

The present invention exploits the realisation that by combining the test sections in this novel way, test zones can be laterally spaced about the optic axis of the imaging equipment, rather than rotationally disposed therearound, so that each test zone can lie on a mirror axis of the imaging equipment in use and reduce this problem.

The key to achieving this objective lies in the novel way in which the mark within a test zone is constituted. In a test zone in accordance with the invention a first mark section from a first layer and a second mark section from a second layer co-operate together and are adjacently disposed such that each test zone comprises co-operably disposed and aligned mark structures from both layers under test. Combining mark structures from both layers in a single test zone in this way allows the overall pattern of multiple test zones to be simplified relative to typical examples in the prior art, and in particular then allows test zones to be laterally spaced about the optic axis without loss of X-Y information. The novel composition of each test zone is particularly suited to the specific features of overlay metrology technology, and exploits these to the full to provide an effective means of reducing asymmetry errors.

The preferred square or rectangular symmetry of the test zones can be retained. Accordingly, each test zone preferably has a generally square or rectangular outline shape, the rectangular directions corresponding to the said first and second directions and to the mirror axes of the imaging equipment in use. Generally square test zones are especially to be preferred. The lateral spacing means each pair of zones can be disposed in use to have mirror symmetry about an axis of the imaging apparatus, with the mid point at the optical centre thereof. Preferably, the test zones in a pair are identically sized and shaped. Where more than one pair is present all of the test zones may be identically sized and shaped, or different pairs may be differently sized and shaped. Where more than one zone pair is present, the mid points for each pair are co-located.

A particular advantage of the invention is that existing metrology tools may be simply adapted to measurement of the present target designs, avoiding the costs involved in retooling that radically different methods would require.

Each mark portion is associated with a layer under test, so that the measured overlay error is representative of the misalignment between the respective layers. Overlay metrology marks in accordance with the invention are suited to measurement of overlay errors between layers, in particular but not limited to consecutive layers. Where the overlay mark is used to aid measurement of misregistration between different layers, the first mark portion is laid down upon a first lower layer, and the second mark portion is laid down upon a second layer above the said first layer, in particular on an uppermost layer, such that the test structures of the lower layer are detectable through the upper layer. The upper mark portion serves as an alignment marking, and the lower mark portion as the reference marking.

In a simplest embodiment of the invention the number of test zones can be reduced to two. The first and second mark sections of the first zone comprise closely adjacent mark structures in parallel array in a common direction, respectively part of the first (or overlay) mark portion and the second (or reference) mark portion. The first and second mark sections of the second zone are similar arrays but disposed at right angles thereto. Only two test zones are needed to give information in both X and Y directions.

These two test zones are laterally spaced along a line which is parallel to the direction of the test structures in one zone, and perpendicular in the other zone. As a result both test zones can be located generally on an axis of mirror symmetry of the scanning apparatus. Improved accuracy in overlay error measurements is offered by this closer association with the axis of symmetry of typical imaging apparatus.

In an alternative embodiment the mark comprises more than one pair of test zones. Each pair is laterally disposed equidistantly about a common centre in one or other of the said two directions. In a particularly preferred embodiment, a single such pair is disposed in a first direction and a single such pair in a second direction. The first and second mark sections of each zone comprise closely adjacent mark structures in parallel array in a common direction, respectively part of the first (or overlay) mark portion and the second (or reference) mark portion. The first and second mark sections of two zones are in the first direction and the first and second mark sections of the other two zones in similar arrays but disposed at right angles thereto. This may be achieved either in that a zone in each pair has mark structures oriented in each direction, or in that both zones in a pair have a common orientation perpendicular to that of the other pair.

These two test zones in each pair are laterally spaced in respectively an X and Y direction about common centres. In particular they are equidistantly spaced. As a result all test zones can lie about an axis of mirror symmetry of the scanning apparatus, which is not possible in conventional overlay marks comprising four test zones in a square array. The extra information such a four zone array offers can be retained without losing the preferred square or rectangular geometry.

The mark structures comprising each mark section are elongate rectangular structures in parallel array. It will be understood that provided the general elongate rectangular outline for these test structures is maintained, the structures need not be single monolithic rectangular structures. As will be familiar to those skilled in the art, each rectangular test structure may be made up of a series of sub structures. For example, each elongate rectangular test structure may comprise a row or column as the case may be of smaller constituent test structures, for example a row or column of squares.

Each elongate rectangular test structure and/or each constituent test structure may comprise sub structures down to design rule limits in the manner which will be familiar to address issues of process induced inaccuracy, as is well known. Suitable arrangements, familiar to those skilled in the art, include parallel arrays of elongate rectangular sub-structures in either direction, arrays of square sub-structures, circles in square or hexagonal array, arrays of holes within a suitably shaped test structure and any combinations or other like patterns. Sub-structure dimensions are set by design rule limits, being typically for present techniques of the order of 100 to several hundreds of nanometres. However advances in manufacturing processes are likely to further reduce these dimensions in the future.

The mark sections each comprise elongate rectangular structures in a repeating array. Preferably the pitch is of constant period in each mark section. Preferably the period is identical in all mark sections. In a particular preferred configuration, all rectangular test structures in a test zone, and more preferably in the whole mark, have identical widths and spacing. In this way, test structures from the overlay and test structures from the reference in a given test zone are all in alignment when the mark is correctly aligned. In particular, each test structure abuts its neighbour to form in combination therewith a single elongate rectangular mark structure when in correct alignment.

Each test zone should preferably have a rectangular, and in particular a generally square outline. Given typical overall mark sizes of 25 μm, each test zone is conveniently around a 10 to 12 μm square.

The dimensions of each test structure within each zone and the spacing thereof will be optimally determined by and are therefore preferably set with reference to the resolution limit of the imaging microscope. In one implementation therefore each test structure will have a width of around 0.5 to 2 μm. Spacing between test structures in the array will preferably be between one half and two structure widths, and in particular around 1 structure width. This will maximise feature density at the resolution limit of the imaging device. Any specific design embodying the principles of the invention will increase the number of feature transitions when compared with many previous designs. Each mark section then comprises several test structures in each direction, preferably at least five, while fitting comfortably into a conventional mark area. The additional image detail provides more information content in the image, providing for an improvement in measurement precision.

In use with a standard imaging device, the test structures making up each mark portion are to be aligned with the vertical and horizontal grid directions of each array parallel to the X-Y symmetry lines of the imaging device. It has been noted that optimal performance depends on measurement being centred on the optic axis of the imaging device. In use the optic axis of the imaging instruments will be located at a point generally equidistant between each test zone pair along a notional line between the centres thereof.

The test structures making up the array comprising each mark portion may be laid down by any suitable technique known to those skilled in the art, in particular the photolithographic techniques above described.

In a preferred embodiment a recognition key is provided for use in association with an overlay mark as hereinbefore described. In accordance with the embodiment an identification portion is provided in association with a first mark portion, comprising a simple optically readable mark divided into a small number of pattern areas in each of which areas a marling may be present or absent, the pattern of such markings providing a unique identification key so as to serve to identify the first mark portion.

An identification portion in accordance with the invention is associated with the alignment mark and gives a simple digital identification of the alignment mark, ensuring the correct mark is selected. The identification portion thus acts as a pattern recognition key.

A similar identification portion may be associated with other marks on a wafer, whereby the embodiment of the invention comprises an overlay metrology mark system for the whole wafer ensuring the correct marks are selected at all times. The probability of locating the wrong overlay metrology mark can be reduced by varying the pattern in adjacent marks, increasing the distance to a potentially confusing pattern recognition key.

In particular, the identification portion is laid down with the first mark portion, for example at the same time and for example on the same layer. The identification portion is conveniently located proximal to the first mark portion, for example comprising a part thereof.

The recognition key comprises a simple pattern exhibiting a small number of discrete alternative shapes to give a digital identifier. The pattern is adapted to be optically readable by standard imaging equipment at the same time as the primary alignment mark is imaged, requiring no major equipment modification and only minimal modification to image analysis. The recognition key is preferably laid down by the same process as the primary mark, for example employing photolithographic techniques. However, the pattern making up the recognition key is designed to be optically imaged for recognition purposes only, and not for determination of alignment differences. The structure can accordingly be made from structural element(s) which optimise this aspect, and might therefore be substantially larger than the structures making up the primary alignment mark.

The recognition key pattern comprises a small number of pattern areas, for example between four and eight, in each of which areas a marking may be present or absent, the pattern of such markings thus providing the unique identification. In particular, in each pattern area a marking is either substantially entirely present or substantially entirely absent. The arrangement of which pattern areas are present and which are absent gives the unique key. For example, for simplicity it might be preferable if a mark is absent in a single pattern area.

Preferably, the recognition key pattern has a generally square or rectangular outline. This is particularly the case where the corresponding primary mark has generally square or rectangular symmetry. In particular, the horizontal and vertical directions of such a square or rectangular outline correspond to the horizontal and vertical directions of a similarly square or rectangular overlay mark, and in use with the x and y directions of symmetry in the optical imaging apparatus. As a consequence of this geometry, each pattern area is similarly preferably square or rectangular. The recognition key pattern then preferably comprises a linear or two-dimensional array of such pattern areas, for example consisting of between one and four such areas in each of a row and column direction, corresponding in use to the x and y directions in the optical imaging apparatus.

Each pattern area preferably has dimensions of between 1 and 4 μm, and particularly preferably comprises a 1 μm square. All pattern areas making up the recognition key pattern are preferably identically sized and shaped.

In particular, the key pattern comprises a square or rectangular area sub-divided into a two dimensional array of square or rectangular pattern areas.

This gives a highly readable identification mark, maintaining the square or rectangular symmetry of many of the alignment marks with which it is intended to be used, and accordingly easily readable by the imagining equipment. Suitable overall pattern dimensions are from 2 to 8 μm, allowing pattern area dimensions of 1 to 2 μm for ease of imaging. In particular pattern areas are 1 to 2 μg/m squares.

In a particular embodiment the recognition key pattern comprises a square divided into four equal sub-square pattern areas as above described. Each sub-square pattern area is either present or absent in the recognition key pattern. Mostly preferably, the recognition key pattern comprises a generally L-shaped mark, wherein there are four such sub-square pattern areas in one of which a mark absent. The mark provides four distinct patterns (dependent upon the orientation of the L-shape) which are easily readable and distinguished. This is sufficient for many purposes.

It is well known that optimal performance depends on measurement being centred on the optic axis of the imaging device. Overlay marks are usually symmetric about this centre, with the overlay error being the measured displacement of the centres. Conveniently, to avoid introducing asymmetry, the recognition key may be located at the centre. Alternatively, a plurality of recognition keys are provided away from the centre.

The advantages of existing target designs are retained. The measurements are made from a single image so that speed of measurement is not compromised. The measurement is made using an optical image, so that existing imaging tools can be used. Overlay error may be quantified using any suitable known or specifically developed image processing technique.

Thus, in accordance with the present invention in a second aspect a method for providing an overlay metrology mark to determine the relative position between two or more layers of an integrated circuit structure comprises the steps of:

laying down a first mark portion in association with a first layer;

and laying down a second mark portion in association with a second layer; the first and second mark portions being so structured as to together constitute, when the mark is properly aligned, at least one pair of test zones, each test zone comprising a first mark section formed as part of the first mark portion and a second mark section formed as part of the second mark portion each comprising a plurality of elongate rectangular mark structures in parallel array adjacently disposed to form the said test zone test zone such that the mark structures in each test zone are in alignment within the test zone, said alignment being in a first direction in half of the test zones and in a second direction substantially at 90° thereto in the other test zones, and wherein the test zones making up the or each pair are laterally displaced relative to each other along one of the said directions.

Similarly, in accordance with the present invention in a third aspect a method for determining the relative position between two or more layers of an integrated circuit structure comprises the steps of:

laying down a first mark portion in association with a first layer, and laying down a second mark portion in association with a second layer, the first and second mark portions being so structured as to together constitute at least one pair of test zones as hereinabove described;

optically imaging the two test zones in the said first and second directions; collecting and digitizing the image;

numerically analysing the digitized data to obtain a quantified measurement of the misalignment of the first and second mark portions.

It is important to emphasise that each mark portion making up the overlay metrology mark is laid down in direct association with the associated layer, and in particular is preferably developed within or on the surface of the said layer. For example each mark portion is printed on the said layer. Each mark portion is preferably laid down by a photolithographic process.

In a preferred embodiment of the method of the invention, the overlay metrology mark incorporates an identification mark serving as a recognition key as hereinbefore described. The method thus comprises, in association with the step of laying down of an alignment mark portion associated with a second layer, and for example contemporaneously therewith,

laying down in association with the said mark portion an identification portion comprising a simple optically readable mark divided into a small number of pattern areas in each of which areas a marking may be present or absent, the pattern of such markings providing a unique identification key so as to serve to identify the alignment mark portion.

Optical imaging of the mark is preferably carried out using imaging microscopy, and for example bright field microscopy. Other preferred features of the methods will be understood by analogy with the foregoing.

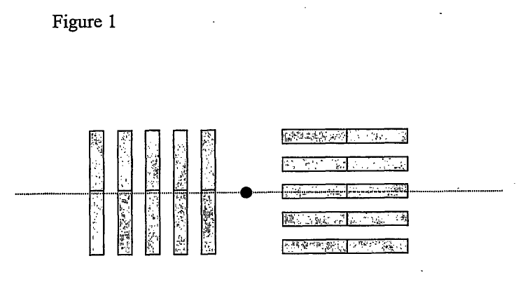

The invention will now be described by way of example only with reference to FIGS. 1 to 6 of the accompanying drawings, wherein:

FIGS. 1 to 3 are general schematics of an overlay metrology mark in accordance with three embodiments of the invention;

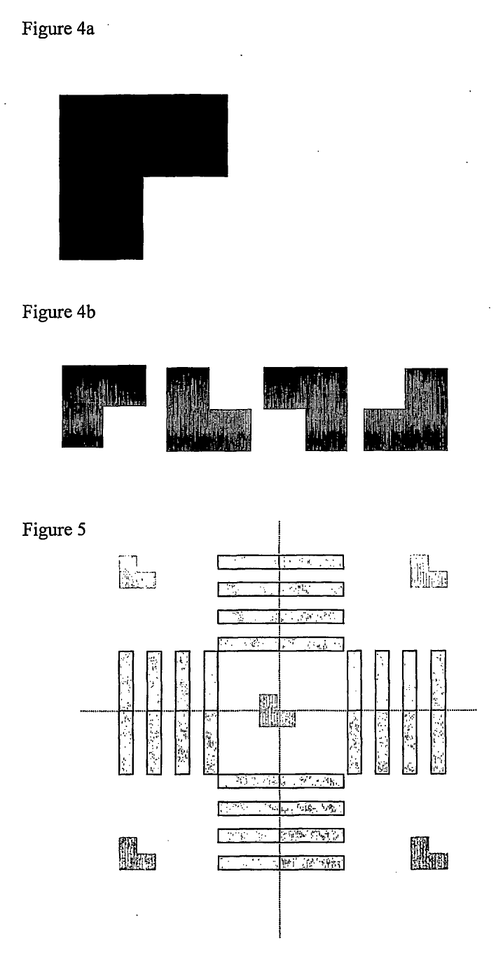

FIG. 4 is a plan view of a suitable identification recognition key for use in accordance with a preferred embodiment of the invention;

FIG. 5 illustrates use of the key of FIG. 4 in association with the mark of FIG. 3;

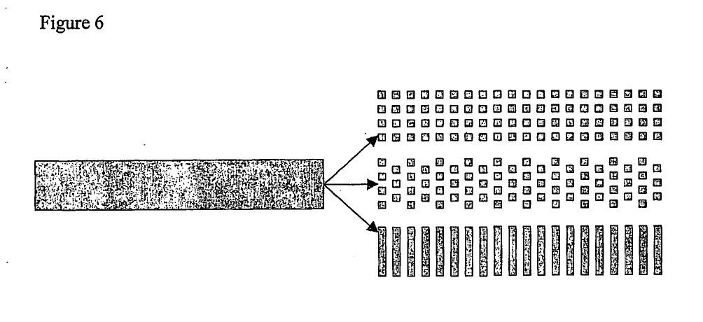

FIG. 6 illustrates example substructures for a mark structure for use with a mark in accordance with the invention.

The overlay metrology mark comprises a first or reference mark portion on a first lower layer and a second or alignment mark portion on a second layer above the first layer, for example an uppermost layer. Where complete marks are illustrated in the figures, the second mark portion is represented by darker grey-shaded structures. The first mark portion, configured to be at least partially visible in conjunction with the second, is represented by lighter grey-shaded structures.

The invention lies in the arrangement of test structures in a repeating array. The structures and any sub-structures making up the test structures are formed using any suitable processes. Typically these will include lithographic processes that are generally known in the art. Misalignment is measured using imaging systems and image analysis techniques, which may be standard systems and techniques that are generally known in the art or systems and techniques modified to be optimized specific to the marks in accordance with the invention.

FIG. 1 illustrates a top plan view of an alignment mark according to one embodiment of the invention. The mark is shown in the intended configuration that results when the tested layers of a structure are in proper alignment. The mark consists of two mark portions, one on each layer, so serving as overlay and reference.

In FIG. 1 there are two test zones. Each zone has an overall square shape. The zones are spaced along the dotted line equidistantly about the dot so that each square zone is located mirror-symmetrically on the dotted line. In use this is an X or Y mirror direction of the bright field imaging microscope or other device, with the dot being the optic centre.

In this implementation, four groups of linear mark structures are shown. The lines in the first two groups are oriented vertically making up the first zone, while the lines in the final two groups are oriented horizontally. The pairs of lines are designed to be printed exactly side by side. The overlay measurement is the relative displacement of one set of lines from the other, which may conveniently be measured using any standard or specially modified technique and analysis.

To optimise differentiation between reference and overlay the line pitch is arranged to be significantly larger than process tolerance limits for overlay error. The pitch of the lines is also arranged to match the resolution of the imaging microscope. In the example the line pitch is constant, giving the array a constant periodicity. Line pitch is conveniently broadly equal to line width, both being around 1 μm in the illustrated implementation.

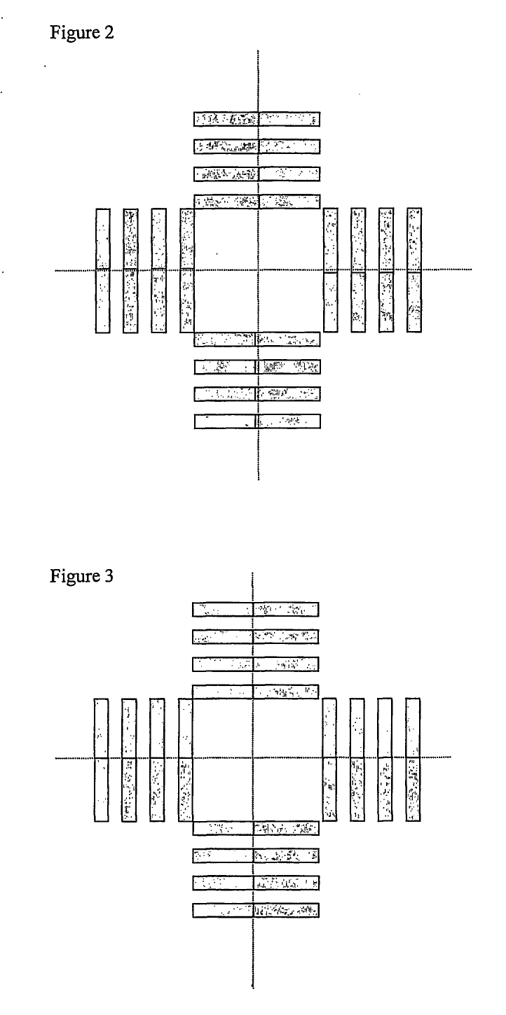

FIG. 2 illustrates a top plan view of an alignment mark according to one embodiment of the invention. The mark is shown in the intended configuration that results when the tested layers of a structure are in proper alignment. The mark consists of two mark portions, one on each layer, so serving as overlay and reference.

In FIG. 2 there are four test zones. Each zone has an overall square shape as in FIG. 1. The zones are identical in size and spaced along the dotted lines equidistantly in pairs about a common centre. In use these are X and Y mirror directions of the bright field imaging microscope or other device, with the intersection of the lines being the optic centre.

Again each zone consists of an array of lines from the overlay and an array from the reference. The lines in two of the zones are oriented vertically, while the lines in the final two zones are oriented horizontally. The pairs of lines in each zone are designed to be printed exactly side by side. This produces a cross pattern similar to that of traditional targets, but with each zone symmetrically on the axes whilst retaining a square geometry. This design meets the goals of separation of the target lines from each layer in order to avoid interaction between the images, axial symmetry and offers more image detail than other designs. The use of isolated groups of lines for each layer also permits application of novel image analysis techniques.

FIG. 3 illustrates a top plan view of an alignment mark representing a minor variant of FIG. 2. Again, there are four zones of similar line arrays, but the orientation within equivalent zones is varied. This is intended to illustrate that provided zones are present to give both X and Y measurement, it is not critical whether the linear structures making up the two zones in each pair share an orientation or are in opposite orientation.

FIG. 4a shows a basic recognition key suitable for use with the overlay metrology mark of the invention in accordance with a preferred embodiment thereof. The mark is shown in top plan view. Increasingly, new measurement structures do not provide an easy pattern recognition target as there is no isolated well-resolved image in the resist. The key comprises a specific mark printed in the resist layer. The mark consists of a 2 μm square mark area subdivided into a two by two array of 1 μm square pattern areas. Three of these are covered by the mark material and one absent. The effect is to produce a key comprising a 2 μm square from which one corner is omitted, giving a general L-shape.

Any corner may be omitted, allowing four unique pattern recognition targets to be created as illustrated in FIG. 4b. The simplicity of the design makes this easy to image, and easy to distinguish between the four targets, so that the key provides a clear digital identifier of a given overlay mark with which it is associated, and greatly assists in ensuring the correct overlay mark is imaged. Overlay targets can be positioned nearby but will be safe from pattern recognition error if the keys are different. The probability of locating the wrong target can be reduced by varying the omitted corner in adjacent targets, increasing the distance to a potentially confusing pattern recognition key.

FIG. 5 illustrates use of the key of FIG. 4 in association with the marks of FIG. 3. A key is placed centrally within a mark and further keys laid down at the corners. This example is illustrative only of the various arrangements that could be envisaged.

FIG. 6 illustrates example substructures for a mark structure for use with a mark in accordance with the invention. A single individual test structure from those making up each array of a mark in accordance with the invention is shown to the left, being an elongate rectangular structure. Such an individual test structure may optionally be made using design rule sized sub-structures to address issues of process induced inaccuracy, as is well known. In the illustrated three examples on the right, the rectangular structure comprises an array of sub-resolution features (lines, dots or squares etc.) to form the required shape. Because the small features are not resolved, they are not individually visible through the microscope, giving the appearance of a single contiguous structure. The mark-space ratio of the sub-resolution features can be adjusted to meet the optimal performance criteria of the printing process.

1. An overlay metrology mark for determining the relative position between two or more layers of an integrated circuit structure comprising a first mark portion associated with a first layer and a second mark portion associated with a second layer, wherein the first and second mark portions together constitute, when the mark is properly aligned, at least one pair of test zones, each test zone comprising a first mark section formed as part of the first mark portion and a second mark section formed as part of the second mark portion each comprising a plurality of elongate rectangular mark structures in parallel array adjacently disposed to form the said test zone such that the mark structures in each test zone are in alignment in a first direction within the test zone but are substantially at 90° with respect to the mark structures of at least one other test zone in alignment in a second direction, and wherein the test zones making up the or each pair are laterally displaced relative to each other along one of the said directions.

2. An overlay metrology mark in accordance with claim 1 wherein each pair of zones are laterally disposed relative to each other such as in use to have mirror symmetry about an imaging axis of the imaging apparatus.

3. An overlay metrology mark in accordance with claim 1 wherein each mark portion is developed within or on the said layer.

4. An overlay metrology mark in accordance with claim 2 wherein each mark portion is printed on the said layer by a microlithographic process.

5. An overlay metrology mark in accordance with claim 2 wherein each test zone has a generally square or rectangular outline shape, the rectangular directions corresponding to the said first and second directions and to the mirror axes of the imaging equipment in use.

6. An overlay metrology mark in accordance with claim 5 wherein test zones are generally square.

7. An overlay metrology mark in accordance with claim 1 wherein only two test zones are present, and wherein the first and second mark sections of the first zone comprise closely adjacent mark structures in parallel array in a common direction, respectively part of the first mark portion and the second mark portion, the first and second mark sections of the second zone comprise similar arrays but disposed at right angles thereto, and the two test zones are laterally spaced along a line which is parallel to the direction of the test structures in one zone, and perpendicular to the direction of the test structures in the other zone.

8. An overlay metrology mark in accordance with claim 1 comprising more than one pair of test zones, wherein each pair is laterally disposed equidistantly about a common centre in one or other of the said two directions.

9. An overlay metrology mark in accordance with claim 8 comprising a single such pair disposed in a first direction and a single such pair in a second direction.

10. An overlay metrology mark in accordance with claim 9 wherein the first and second mark sections of each zone comprise closely adjacent mark structures in parallel array in a common direction, respectively part of the first mark portion and the second mark portion, and wherein the first and second mark sections of two zones are in the first direction and the first and second mark sections of the other two zones in similar arrays but disposed at right angles thereto, and the two test zones in each pair are laterally spaced in respectively an X and Y direction about common centres.

11. An overlay metrology mark in accordance with claim 1 wherein the elongate rectangular mark structures comprise single monolithic rectangular structures.

12. An overlay metrology mark in accordance with claim 1 wherein the elongate rectangular mark structures comprise arrangements of substructures constituting together a general elongate rectangular outline.

13. An overlay metrology mark in accordance with claim 12 wherein the elongate rectangular mark structures comprises a row or column as the case may be of smaller constituent test structures, for example a row or column of squares.

14. An overlay metrology mark in accordance with claim 1 wherein each elongate rectangular test structure and/or each constituent test structure comprise arrangements of design rule sized sub-structures.

15. An overlay metrology mark in accordance with claim 14 wherein the arrangements of design rule sized sub-structures are selected from parallel arrays of elongate rectangular sub-structures in either direction, arrays of square sub-structures, circles in square or hexagonal array, arrays of holes within a suitably shaped test structure and any combinations of these or other like patterns.

16. An overlay metrology mark in accordance with claim 1 wherein the pitch of the elongate rectangular structures is of constant period in each mark section.

17. An overlay metrology mark in accordance with claim 16 wherein the period is identical in all mark sections.

18. An overlay metrology mark in accordance with claim 16 wherein all rectangular test structures in a test zone have identical widths and spacing.

19. An overlay metrology mark in accordance with claim 1 wherein each test structure has a width of around 0.5 to 2 μm, and wherein spacing between test structures in the array is between ½ and two structure widths.

20. An overlay metrology mark in accordance with claim 19 wherein each mark section comprises at least five test structures in each direction.

21. A method for providing an overlay metrology mark to determine the relative position between two or more layers of an integrated circuit structure comprises the steps of:
laying down a first mark portion in association with a first layer;
and laying down a second mark portion in association with a second layer;
the first and second mark portions being so structured as to together constitute, when the mark is properly aligned, at least one pair of test zones, each test zone comprising a first mark section formed as part of the first mark portion and a second mark section formed as part of the second mark portion each comprising a plurality of elongate rectangular mark structures in parallel array adjacently disposed to form the said test zone such that the mark structures in each test zone are in alignment within the test zone, said alignment being in a first direction in half of the test zones and in a second direction substantially at 90° thereto in the other test zones, and wherein the test zones making up the or each pair are laterally displaced relative to each other along one of the said directions.

22. A method for determining the relative position between two or more layers of an integrated circuit structure:
laying down a first mark portion in association with a first layer, and laying down a second mark portion in association with a second, the first and second mark portions being so structured as to together constitute at least one pair of test zones as hereinabove described;
optically imaging the two test zones in the said first and second directions;
collecting and digitizing the image;
numerically analysing the digitized data to obtain a quantified measurement of the misalignment of the first and second mark portions.

23. The method of claim 22 wherein optical imaging of the mark is carried out using bright field microscopy.

24. The method of claim 22 wherein each mark portion is developed within or on the said layer.

25. The method of claim 22 wherein each mark portion is laid down by a microlithographic process.

26. (canceled)
